(19) United States
(12) Patent Application Publication
(10) Pub. No.: US 2004/0232954 A1
(43) Pub. Date: Nov. 25, 2004

(54) Signal generator device, method for generating a signal and devices including such a signal generator device

(76) Inventor: Paulus Thomas van Zeijl, Veldhoven (NL)

Correspondence Address: NIXON & VANDERHYE, PC, 1100 N GLEBE ROAD, 8TH FLOOR, ARLINGTON, VA, 22201-4714, US

(21) Appl. No.: 10/482,939

(22) PCT Filed: Jan. 8, 2002
(86) PCT No.: PCT/EP02/00268

(30) Foreign Application Priority Data
Jul. 6, 2001 (NL) N1/01/514

(51) Int. Cl. H03B 19/00

(52) U.S. Cl. 327/116

(57) ABSTRACT

A signal generator device which includes a generator input (51a, 51b) for receiving input signals; a frequency multiplication section (7) including: at least two frequency multiplication inputs (551-555) communicatively connected to the generator input (51a, 51b), for receiving each at least one phase shifted signal having a phase difference with respect to the other phase shifted signal; pulse generator sections (741-745) connected to at least one of said frequency multiplication inputs for generating an output signal if said phase shifted signals has a transition from a first state to a second state. The signal generator device further includes at least one generator output (72) connected to at least one of said at least one pulse generator sections for transmitting said output signal.

The invention relates to a signal generator device and a method for generating signal of a harmonic frequency. The invention further relates to electronic devices, e.g. a receiver device, a transmitter device, a transceiver device including a signal generator device according to the invention.

From the U.S. Pat. No. 5,990,712 a harmonic generator is known. This publication describes a harmonic generator which converts an input signal at a fundamental frequency into an output signal at a harmonic frequency. A non-linear device converts the input signal into an intermediate signal in which the harmonic frequency has a maximized amplitude determined by a conduction angle. A harmonic filter produces a filtered signal proportional to the amplitude of the harmonic frequency within the intermediate signal. A detector produces a control signal proportional to the amplitude of the filtered signal. A control circuit produces a variable bias signal for the non-linear device, the bias signal being proportional to the amplitude of the control signal and determining the conduction angle. An output filter converts the intermediate signal into an output signal at the harmonic frequency.

However, the known signal generator is complex of design because of the large number of components. Furthermore, the harmonic filter, the detector and the control circuit form a feedback loop, which makes the signal generator even more complex. The invention seeks to overcome this disadvantage. It is therefore a goal of the invention to provide a less complex signal generator device.

The invention seeks to achieve said goal by providing a signal generator device, at least including a generator input for receiving at least one input signal having an input frequency; a frequency multiplication section at least including: at least two frequency multiplication inputs, each communicatively connected to the generator input for receiving each at least one phase shifted signal having a phase difference with respect to the other phase shifted signal; at least one pulse generator section connected to at least one of said frequency multiplication inputs for generating an output signal if said phase shifted signals has a transition from a first state to a second state, said signal generator device further including at least one generator output connected to at least one of said at least one pulse generator sections for transmitting said output signal.

Such a signal generator device is simple of design, because of the small number of simple components used in the device. Furthermore, the design of device may easily be adapted, for example by connecting of disconnecting pulse generator sections. Also, a signal generator according to the invention is especially suited for implementation in an integrated circuit, because the device may be implemented using components used in logical circuits, such as AND-ports and transistors

Furthermore, the invention provides a method for generating a signal of a predetermined frequency at least including receiving at least two input signals having a phase difference with respect to each other; generating an output signal if one of said input signals has a transition from a first state to a second state.

Such a method is simple and may be performed with a device for generating a frequency according to the invention.

Particular embodiments of the invention are set out in the dependent claims

Further details, aspects and embodiments of the invention will be described with reference to the figures in the attached drawing.

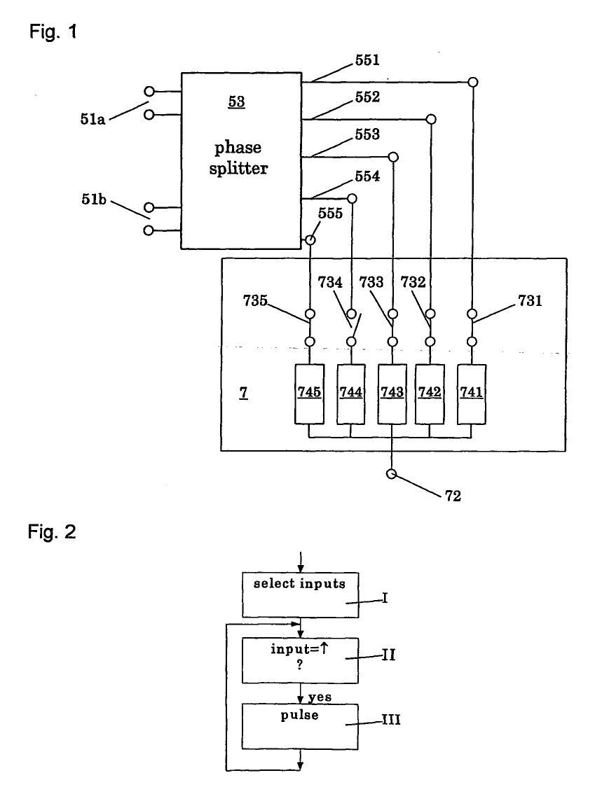

FIG. 1 shows a block diagram of an example of an embodiment of a signal generator device according to the invention.

FIG. 2 shows a flow-chart of an example of an embodiment of a method according to the invention.

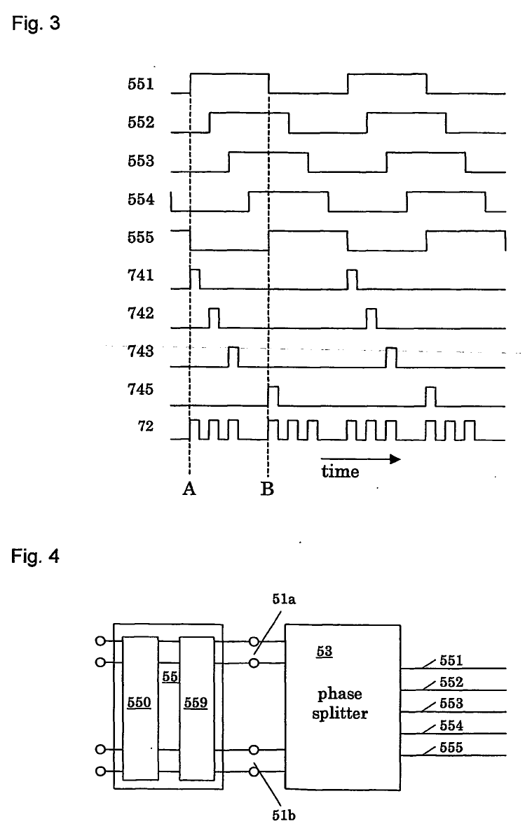

FIG. 3 shows the development in time of phase splitter output signals and signals in successive steps of a signal generation method according to the invention.

FIG. 4 shows a block diagram of a first example of an embodiment of a phase splitter section for a signal generator device of the present invention.

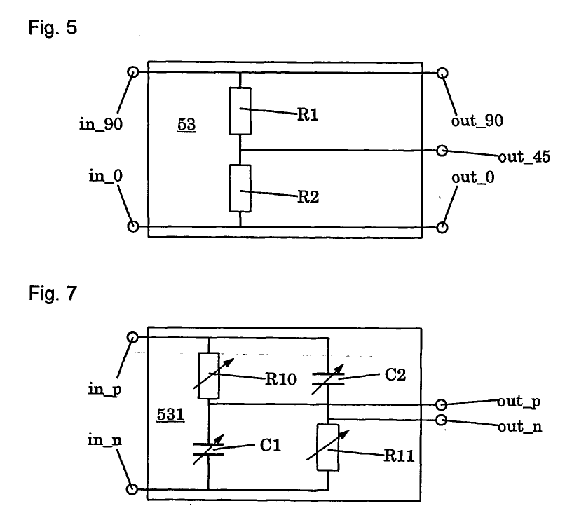

FIG. 5 shows a circuit diagram of a second example of an embodiment of a phase splitter section for a signal generator device of the present invention.

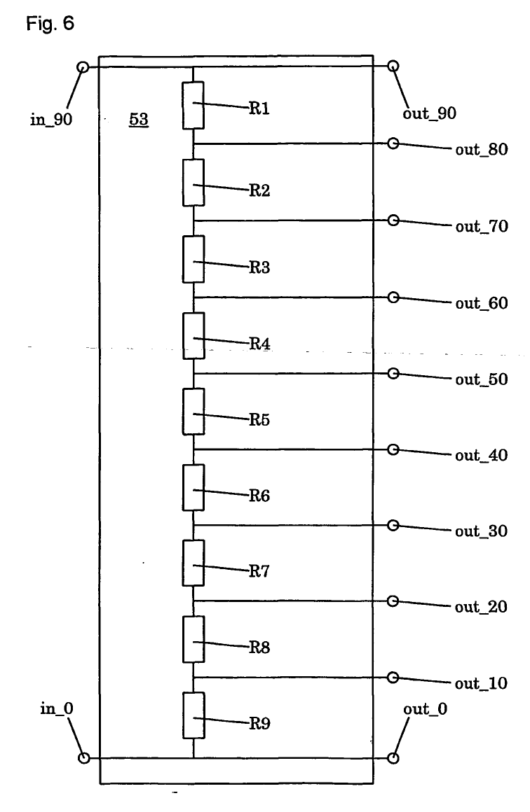

FIG. 6 shows a circuit diagram of a third example of an embodiment of a phase splitter section for a signal generator device of the present invention.

FIG. 7 shows a block diagram of an example of an embodiment of a phase shifter section for a signal generator device of the present invention.

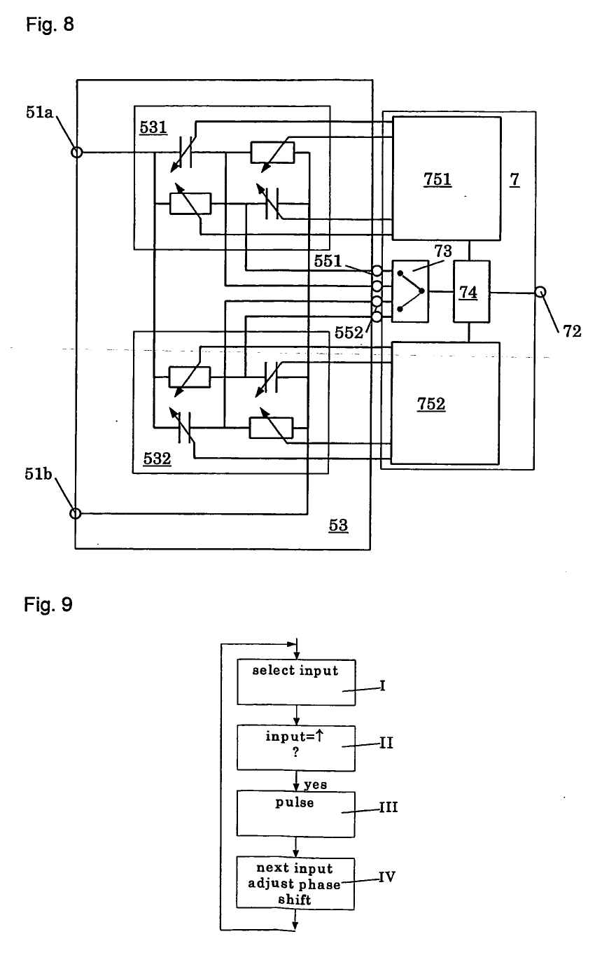

FIG. 8 shows a block diagram of an example of an embodiment of a signal generator device according to the invention in which a phase shifter section as shown in FIG. 7 is implemented.

FIG. 9 shows a flow chart of a second example of a frequency multiplication method according to the invention.

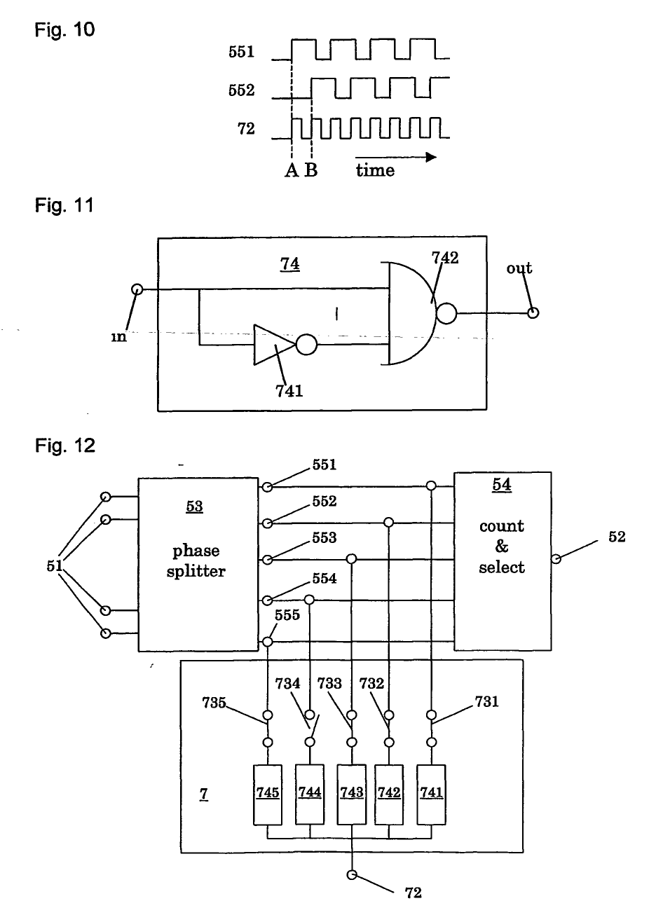

FIG. 10 shows the development in time of phase splitter output signals and a generator output signal in a signal generation method according to the invention, as may be performed by the device of FIG. 8.

FIG. 11 shows a block diagram of an example of a pulse generator device for a signal generator device as shown in FIGS. 1 and 8.

FIG. 12 shows a block diagram of an example of an embodiment of a signal generator device according to the invention combined with a frequency generator device.

A block diagram of a signal generator device according to the invention, is shown in FIG. 1. The shown signal generator device has a phase shifter or phase splitter section 53 and a frequency multiplication section 7. The phase splitter section 53 has two generator inputs 51a,51b and a plurality of shifter outputs 551-555. The frequency multiplication section 7 has a plurality of frequency multiplication inputs communicatively connected to the shifter outputs and depicted in FIG. 1 as coinciding with the shifter outputs 551-555.

The frequency multiplication device 7 further includes a plurality of switches 731-735 each connected to one of the frequency multiplication inputs 551-555 and connected to a pulse generator device 741-745. The pulse generator devices 741-745 are further connected to a generator output 72.

Input signals having a phase difference with respect to each other may be received at the generator inputs 51a,51b. At the shifter outputs 551-555 shifter output signals derived from the input signals may be presented. In FIG. 1, a first balanced input signal is applied to the phase splitter section 53 at one of the generator inputs 51a-51b and at the other input a second balanced input signal is applied to the phase splitter section 53. The second balanced signal differs in phase with respect to the first balanced input signal. In the shown example, it is assumed that the second balanced signal is 90 degrees shifted in phase with respect to the first balanced input signal. Both signals are usually already available in many types of devices, like for instance complex transceivers with image rejection.

Based on the signals presented at the generator inputs 51a,51b the phase splitter section 53 generates phase shifted output signals and transmits the phase splitted output signals via phase splitter output connections 551-555 to the frequency multiplication section 7. In the example shown in FIG. 1, the phase of the signals at each of the shifter output connections 551-555 differs with respect to the signal at all the other shifter output connections. The respective phase differences are listed in table 1, wherein the phase at output 551 is assumed to be 0 degrees.

TABLE 1

| output | phase (degrees) |
|---|---|
| 551 | 0 |
| 552 | 45 |
| 553 | 90 |
| 554 | 135 |
| 555 | 180 |

The shifter output signals are used for generating signals of harmonic or other frequencies based on the frequency of the input signal. The frequency multiplication section 7 of FIG. 1 may perform a method as represented by the flow-chart in FIG. 2. First, in selecting step I, the desired frequency multiplication inputs are selected, which in the example of FIG. 1 are inputs 731-733 and 735. In the next step II, an upgoing transition is detected at one of the inputs and in step III a pulse is generated. Thereafter, steps II and III are repeated as long as desired.

The development in time of the shifter output signals is shown in FIG. 3 for each of the shifter outputs 551-555. In FIG. 3 the development in time of signals at the output of pulse generators 741-745 and the frequency multiplication output 72 is also depicted. Thus, FIG. 3 signals in successive stages of a signal generation according to the invention are shown. If one of the phase shifted output signals at the shifter outputs has an upgoing transition, the pulse generator connected to the specific output generates a small pulse. For example, at the moment indicated with dotted line A the signal at shifter output 551 has an upgoing transition and the pulse generator 741 connected to this shifter output generates a pulse. Likewise, at the moment indicated with dotted line B the signal at shifter output 555 has an upgoing transition and the pulse generator 745 generates a pulse. The outputs of the pulse generators are added to each other. This addition results in a generated signal at the signal generator output 72. In FIG. 1, the pulses are combined in a relatively simple manner by connecting the outputs of the pulse generators to each other, however other ways of combining the pulses may likewise be applied. For example, by adding currents, using (N)AND-, or (N)OR-gates

In the device of FIG. 1, the switches 731-735 communicatively connect the pulse generator devices 741-745 and the shifter outputs 551-555 in a conducting state of the switches. In a non-conducting state of the switch devices 731-735 the pulse generator devices are not communicatively connected to the shifter outputs.

In FIG. 1, the switch 734 is in the non-conducting state and the switches 731-733,735 are in the conducting state. By combining the appropriate shifter outputs with the switches, the required frequency will be available at the output 72 of the generator 7. In general, every higher order frequency or combination of higher order frequencies of the frequency of the phase splitter input signal may be generated. For example, if all switches 731-735 are closed, the 4^{th} harmonic of the signal will be generated and if only switches 731,733 and 735 are closed, the second harmonic will be generated.

If, in use, only a single frequency has to be generated, the pulse generator device may be connected directly to the frequency multiplication inputs, instead of via the switch devices. Thereby, the signal generator will be even less complex, however the frequency of the output signal is not adjustable anymore.

A signal generator device according to the invention is of a simple design and may be adapted easily to different requirements by connecting or disconnecting one or more of the pulse generator devices to or from one or more of the shifter outputs, for example by switching one or more of the switches to either the conducting or the non-conducting state. Furthermore, digital control of the signal generator device is possible such that digital programming is very easy.

In the example of FIG. 1 a phase splitter device as shown in FIG. 4 may be used. The inputs 51a,51b of the phase splitter section 53 of FIG. 4 are connected to a phase calibration section 55. The phase calibration section 55 ensures the required phase difference between the input signals of the section 53, i.e. in the example given 90 degrees. The phase calibration section 55 includes a phase detector circuit 550 which detects the phase difference of its input signals. The phase detector circuit 550 controls a phase shifter circuit 559 which shifts the phase of the signal to the required phase difference. If the phases of the respective signals are known to be sufficiently accurate, the phase calibration section may be omitted in the signal generator device.

The phase splitter section 53 may be implemented as shown in FIG. 5. The phase splitter section of FIG. 5 is a phase splitter section 53 which generates a signal with a phase of 45 degrees at an output out_{—}45. At an input in_{—}0 an input signal is provided. The same input signal shifted 90 degrees in phase is provided at an input in_{—}90. As explained, a +90 or −90 degrees phase shifted signal is usually available in image reject devices and other devices. The inputs in_{—}0, in_{—}90 are connected via resistors R1 and R2. At the node between the resistors R1, R2, the output out_{—}45 is connected. The signal s_{—}45 at output out_{—}45 has a phase shifted over 45 degrees with respect to the signal at input in_{—}0, because:

$$\begin{matrix}s\_ 45 = sin ( wt ) + sin ( wt + 90 ° ) \\ = 2 sin ( \frac{wt - wt - 90 °}{2} ) sin ( \frac{wt + wt + 90 °}{2} ) \\ = 2 sin ( 45 ° ) sin ( wt + 45 ° ) \\ = \sqrt{2} sin ( wt + 45 ° )\end{matrix}$$

The type of phase-splitter shown in FIG. 5 may be extended with more resistors and output contacts. For example in FIG. 6, a phase splitter is shown wherein signals with a 10 degree phase resolution between 0 and 90 degrees are available at outputs out_{—}0-out_{—}90. The outputs out_{—}0-out_{—}90 are connected with resistors R1-R9. The resistance of the resistors R1 and R2 and R1-R9 resp. in FIGS. 3 and 4 may be selected such that the contribution of the two input signals is equal. For the splitter shown in FIG. 6 this criterion results in the values listed in table 2.

required phase difference between the input signals of the section 53, i.e. in the example given 90 degrees. The phase calibration section 55 includes a phase detector circuit 550 which detects the phase difference of its input signals. The phase detector circuit 550 controls a phase shifter circuit 559 which shifts the phase of the signal to the required phase difference. If the phases of the respective signals are known to be sufficiently accurate, the phase calibration section may be omitted in the signal generator device.

The phase splitter section 53 may be implemented as shown in FIG. 5. The phase splitter section of FIG. 5 is a phase splitter section 53 which generates a signal with a phase of 45 degrees at an output out_{—}45. At an input in_{—}0 an input signal is provided. The same input signal shifted 90 degrees in phase is provided at an input in_{—}90. As explained, a +90 or −90 degrees phase shifted signal is usually available in image reject devices and other devices. The inputs in_{—}0, in_{—}90 are connected via resistors R1 and R2. At the node between the resistors R1, R2, the output out_{—}45 is connected. The signal s_{—}45 at output out_{—}45 has a phase shifted over 45 degrees with respect to the signal at input in_{—}0, because:

$$\begin{matrix}s\_ 45 = sin ( wt ) + sin ( wt + 90 ° ) \\ = 2 sin ( \frac{wt - wt - 90 °}{2} ) sin ( \frac{wt + wt + 90 °}{2} ) \\ = 2 sin ( 45 ° ) sin ( wt + 45 ° ) \\ = \sqrt{2} sin ( wt + 45 ° )\end{matrix}$$

The type of phase-splitter shown in FIG. 5 may be extended with more resistors and output contacts. For example in FIG. 6, a phase splitter is shown wherein signals with a 10 degree phase resolution between 0 and 90 degrees are available at outputs out_{—}0-out_{—}90. The outputs out_{—}0-out_{—}90 are connected with resistors R1-R9. The resistance of the resistors R1 and R2 and R1-R9 resp. in FIGS. 3 and 4 may be selected such that the contribution of the two input signals is equal. For the splitter shown in FIG. 6 this criterion results in the values listed in table 2.

phase shift and using each of the shifter outputs 551-552 for a multiple of signals with different phase shifts.

In the example of FIG. 8, the frequency multiplication section 7 sets the phase shift of the shifter section 53 to a predetermined value with phase shift adjuster sections 751 and 752, as is described below. The switch section 73 in the frequency multiplication section 7 selects one of the frequency multiplication inputs 551-552 and the pulse generator 74 generates a pulse if the signal from the selected input has an upgoing transition. In FIG. 8, a first frequency multiplication input 551 is selected. After the signal from the input 551 has had an upgoing transition, a second shifter output 552 is selected by switching the switch 73. The second shifter output 552 is set to a different phase shift and the operation is performed again with the second shifter output. Hereby, for each repetition of the signal generation method the phase shift is different but not all the shifted signals need to be available at the same time and the number of shifter outputs is reduced.

In the signal generator device shown in FIG. 8, the frequency multiplication section 7 may perform an operation according to the flow-chart shown in FIG. 9. Of the shifter outputs 551-552 only one at the time is actually used as input to the frequency multiplication section 7. The development in time of the signals at the phase shifter outputs 551, 552 and the generator output 72 is shown in FIG. 10. At the start in step I the phase shift of the signal of a selected one of the shifter outputs 551-552 is set to a phase shift phi by one of phase shift adjusters 751,752.

If the signal from the selected shifter input has an upward transition, as is indicated with arrow dotted line A in FIG. 9, the criterion of step II is satisfied and a pulse is generated by the generator device 74 in step III. In step IV the next frequency multiplication input is selected and the phase shift of the signal presented at the first shifter output 551 is adjusted to a new value and the whole process is repeated.

In the example of an embodiment of a signal generator device as shown in FIG. 8, the phase shifter section 53 differs from the phase splitter devices shown in FIGS. 5 and 6. The phase shifter 53 of FIG. 8 includes two filter sections 531 and 532 each connected to one of the phase shifter outputs 551,552. An example of suitable filter sections 531 (or 532) is schematically shown in FIG. 7. The filter 531 in FIG. 7 is an all-pass filter section. The amplitude of the filter output signal is flat in the frequency domain. The filter section includes two balanced substantially similar filters. A first filter is formed by a resistor R10 and a capacitor C1 and a second filter is formed by resistance R11 and capacitor C2. The phase shift phi of the output signal of each of the filters with respect to the input signal depends directly on the time-constant of the filter. The time constant is equal to the product of the resistance and capacitance. The phase shift phi is substantially equal to:

phi=2 arctan (wRC),

wherein w is the frequency of the signal; R is the resistance of the resistor and C is the capacitance of the capacitor. The time constant of the filter sections 531-532 is adjustable if the resistance and/or the capacity of one or more of the resistors and/or capacitors is adjustable. Thus the phase adjuster sections 751 and 752 set the resistances and/or capacitances in the filter section connected to the selected one of the shifter outputs 551-552 to a predetermined value to obtain the desired time constant and corresponding phase shift. The adjustable resistors R10,R11 may for example be implemented as field effect transitors connected with source or drain to the capacitors The resistance from source to drain may then be controlled by the voltage applied at the gate of the transistor. The capacitor may for example be implemented with a varactor diode, a Gate-Source capacitance in a MOS device, or by switching-in extra capacitors.

If an adjustable phase shifter section is used, the shifter section may also have only one shifter output and the phase shift of the this single output may after each repetition of the division operation be set to a new phase shift. The phase shift may also be adjusted continuously, such that an infinite frequency resolution is realised. Continuously adjustable phases may be realised by e.g. continuously adjusting the resistance in the filter sections (e.g. using Metal Oxide Semiconductor Field Effect Transistors (MOS FETs) operating in the triode region) and/or by using varactors as capacitance and/or using adjustable inductances. The shown filter is an all-pass filter, it is likewise possible to use one or more low-pass filters, one or more high-pass filters or one or more poly-phase filters or a combination thereof.

In the shown examples the phase shifter is in the proximity of the frequency multiplication section. As an alternative, the phase shifter section may be at a different physical location. In devices wherein a number of phase shifted signals is already available, the phase shifter section may logically be implemented in several sections of the entire device and thus not be physically present. For example in balanced image reject receiver front-ends, transmitters and transceivers, signals with 180 degrees and +90 and −90 degrees phase difference are already available and therefore a separate shifter section may not be necessary. Furthermore, the phase-splitter section may be implemented as a ring oscillator section. In general a ring oscillator includes a circular chain consisting of an odd number of inverters.

The pulse generator may be implemented with combinatorial logic, such as AND, NAND, OR or NOR devices. FIG. 11 shows an embodiment of a pulse generator 74, which may be used in the frequency multiplication sections shown in the figs. In the device 74 shown in FIG. 11, the input signal is supplied to an NAND-circuit 742 and to an inverter 741. The inverter 741 inverts and delays the input signal. The NAND-circuit output signal is then a small pulse. By optimising the delay in the inverter 741, or by using multiple inverters, the duty-cycle of the output signal can be made equal to 50%.

It should be noted that in all of the above mentioned implementations it is possible to add a (relatively slowly varying) signal to the phase-shifted signals such that the output signal contains phase and/or frequency modulation. In the examples presented above, the basis used for the phase-splitter is 90 degrees. Other bases can be used as well: e.g. 0 degrees and 135 degrees can also be used.

Furthermore, the 0 and 90 degrees phase-shifter signals may be used as a radio frequency (rf) input in an image reject mixer. In such a mixer the rf input may be combined with Local Oscillator signals. The mixer may be implemented in receiver, transmitter or transceiver devices.

Furthermore, a signal generator device according to the invention may be connected to other signal generator devices for example to provide means to compensate for the spurious frequencies generated by the fractional generator. Also, the frequency of the generated signal may be (continuously) adjusted in order to obtain a frequency or phase modulation, for example by continuously switching the switch devices in FIG. 1 from the conducting state to the non-conducting state or vice versa.

A signal generator device according to the invention may also comprise a frequency divider device. An example of such a signal generator device is shown in FIG. 12. Besides a phase shifter device 53 and a frequency multiplication device 7, the shown signal generator device has a count and select section 54, as is known from the applicants co-pending international patent application PCT/NL01/00514, to which reference is made

1-31. (Canceled).

32. A signal generator device comprising:
a first input for receiving a first input signal;
a second input for receiving a second input signal having a phase difference with respect to said first input signal;
a phase shifter section with a phase splitter section for generating at least one phase shifted signal having a phase difference with respect to said input signals, said phase splitter section including:
a chain of splitter components, said chain having a first end connected to said first input and a second end connected to said second input, said chain including at least two splitter components being connected to each other at a node, and
a plurality of splitter outputs, of which at least one splitter output is connected to said node;
a frequency multiplication section including:
at least two frequency multiplication inputs communicatively connected to the splitter outputs, for receiving each at least one phase shifted signal having a phase different with respect to the other phase shifted signal; and
a pulse generator section each connected to at least one of said frequency multiplication inputs for generating an output signal if said phase shifted signal has a transition from a first state to a second state,
wherein said signal generator device further includes at least one generator output connected to said pulse generator section for transmitting said output signal.

33. A signal generator device as claimed in claim 32, further including:
a switch device having a switch input connected to at least one of said frequency multiplication inputs and a switch output, said switch device in a conducting state having its input electrically connected to it outputs and electrically disconnected from its output in a non-conducting state.

34. A signal generator device as claimed in claim 32, wherein said phase splitter section comprises a resistive splitter, a capacitive splitter, an inductive splitter, or a combination of such splitters.

35. A signal generator device as claimed in claim 34, wherein the chain of splitter components comprises at least two resistors with a resistance selected such that the contribution of the first and second input signals is equal.

36. A signal generator device as claimed 32, further comprising at least a phase calibration section connected to inputs of the phase splitter section.

37. A signal device as claimed in claim 36, wherein the phase calibration section includes a phase shifter circuit for shifting the phase of an input signal; and
a phase detector circuit for detecting a phase difference between at least two input signals and controlling the phase shifter circuit.

38. A signal generator device as claimed in claim 32, wherein said phase shifter section includes at least one filter section having an adjustable time constant and said frequency multiplication section includes at least one phase shift adjuster device for adjusting said adjustable time constant after a predetermined number of periods of said phase shifted signal.

39. A signal generator device as claimed in claim 32, further including at least a frequency divider section communicatively connected to at least one of said generator inputs.

40. A signal generator device as claimed in claim 32, further including at least one phase calibration section for calibrating said at least one phase shifted signal to minimrize spurious frequency components in said output signal.

41. An electronic device including a signal generator device as claimed in claim 32.

42. An electronic device as claimed in claim 41, wherein said electronic device is selected from a group including a receiver device, a transmitter device, a transceiver device.

43. A method for generating a signal of a predetermined frequency, at least comprising:
receiving at least two input signals having a phase difference with respect to each other;
generating at least one phase shifted signal having a phase between said first input signal and said second input signal by means of a chain of splitter components, said chain having first end for receiving the first input signal;
receiving the second input signal at a second end input, said chain including at least two splitter components being connected to each other at a node; and
outputting at said node at least one phase shifted signal with a phase between said first input signal and said second input signal generating an output signal if one of said input signals and said phase shifted signal has a transition from a first state to a second state.

44. A method as claimed in claim 43, wherein said chain of splitter components comprises a resistive splitter, a capacitive splitter, an inductive splitter, or a combination of such splitters.

45. A method as claimed in claim 44, said chain of splitter components comprises at least two resistors with a resistance selected such that the contribution of the first and second input signals is equal.

46. A method as claimed in claim 43, wherein said receiving at least two inputs signals further comprises calibrating a phase of said at least two input signals.

47. A method as claimed in claim 46, wherein said calibrating a phase comprises:
detecting a phase difference between said at least two input signals; and
shifting the phase of an input signal.

48. A method for generating a signal of a predetermined frequency as claimed in claim 43, including:
receiving an input signal;
generating an output signal;
generating at least one phase shifted signal by shifting the phase of said input signal with a first predetermined phase shift;
if said phase shifted signal has a transition from a first state to a second state switching said output signal from a current state to a substantially inverse state;
after a predetermined number of periods of said signal;
performing said step of generating at least one phase shifted signal with a phase shift different from said first predetermined phase shift; and
performing said switching.

49. A method as claimed in claim 48, wherein said generating at least one phase shifted signal includes filtering at least one of said input signals.
